(19) United States
(12) Patent Application Publication
(10) Pub. No.: US 2026/0176088 A1
(43) Pub. Date: Jun. 25, 2026

(54) Wafer Transfer Hand, Wafer Exchange Device, Charged Particle Beam Device, and Vacuum Device

(71) Applicant: Hitachi High-Tech Corporation, Minato-ku, Tokyo (JP)

(72) Inventors: Motohiro TAKAHASHI, Tokyo (JP); Masaki MIZUOCHI, Tokyo (JP); Seiichiro KANNO, Tokyo (JP); Go MIYA, Tokyo (JP); Yuuta YANBE, Tokyo (JP); Takumi NAGAYAMA, Tokyo (JP); Masahiro KAMIGAKI, Tokyo (JP)

(21) Appl. No.: 19/129,540

(22) PCT Filed: Dec. 8, 2022
(86) PCT No.: PCT/JP2022/045303

§ 371 Date: May 13, 2025

(51) Int. Cl. B65G 47/92

(52) U.S. Cl. CPC B65G 47/92

(57) ABSTRACT

A wafer transfer hand includes a hand main body, an electrostatic chuck, and an easily-deformable member, the electrostatic chuck and the easily-deformable member are disposed adjacent to each other on one plane of the hand main body, and the easily-deformable member has a height higher than that of the electrostatic chuck. Accordingly, in the wafer transfer hand, even when an electrostatic adsorption force is reduced, a positional displacement of the wafer can be prevented, and a wafer can be prevented from bouncing due to a residual adsorption force.

### TECHNICAL FIELD

The present disclosure relates to a wafer transfer hand, a wafer exchange device, a charged particle beam device, and a vacuum device.

### BACKGROUND ART

In the related art, in a semiconductor device field, a technique related to a wafer exchange device such as a wafer exchange robot is known. In particular, in a wafer exchange device in a vacuum, it is necessary to operate a robot hand (hereinafter, also simply referred to as a “hand”) at a high speed in order to shorten a wafer exchange time. In addition, with diversification of devices, it is necessary to cope with a wafer that is easily warped.

PTL 1 discloses that, in a substrate transfer device, an end effector including a support member that supports a semiconductor wafer, an electrostatic chuck provided on the support member, and a holding pin as a holding portion formed to protrude from a support surface is used, and the holding pin is provided to be movable along an attachment hole in a direction in which the holding pin protrudes from the support surface, so that even when warpage occurs in the semiconductor wafer, a center portion of the semiconductor wafer that is less deformed due to the warpage is held by the electrostatic chuck, and a region around the center portion is held by the holding pin, and thus the semiconductor wafer can be sufficiently held in accordance with the deformation due to the warpage.

### CITATION LIST

### Patent Literature

PTL 1: WO2012/014442

### SUMMARY OF INVENTION

### Technical Problem

In processes such as manufacturing, measurement, and inspection of a semiconductor wafer, it is necessary to perform a high-speed exchanging operation of the semiconductor wafer in order to increase a throughput which is the number of processed wafers per unit time of the device. A warped wafer may also be handled.

Depending on a type of process, high positional accuracy on a micrometer scale is required at the same time as high-speed wafer exchange. In particular, in a device for handling a wafer with a pattern, as compared with a device for handling a bare wafer without a pattern, it is required to reduce a positional displacement of the wafer at the time of wafer transfer also for positional alignment of a fine circuit.

On the other hand, when the acceleration is increased in order to speed up an operation of the wafer exchange robot in order to shorten the time required for the wafer transfer, an inertial force applied to the wafer increases, the wafer slides on the robot hand, and the positional displacement may increase. In addition, when the slip of the wafer becomes excessive, the wafer may fall in the device, the wafer which is a brittle material may be broken, fragments may be scattered in the device, and it may be difficult to continue use of the device.

Therefore, an increase in a maximum force in a lateral direction (hereinafter, referred to as “resistance to lateral slippage”) that prevents the wafer from slipping on the robot hand of the wafer transfer device is a problem. In addition, when the wafer is warped or when a chemical such as a resist or foreign matter adheres to a back surface of the wafer, if a degree of decrease in resistance to lateral slippage is large, it is necessary to set a safety factor in anticipation of the degree, and it is necessary to significantly reduce an operation speed, which leads to an increase in wafer exchange time. That is, improvement of robustness of resistance to lateral slippage when there is a warped wafer or a foreign matter on the back surface thereof is also a problem.

In the substrate transfer device described in PTL 1, the center portion of the semiconductor wafer is fixed by an electrostatic chuck. In this case, an electrostatic adsorption force of the electrostatic chuck is applied to the semiconductor wafer to obtain a frictional force. Since the electrostatic chuck is formed of ceramics or a polyimide film, a friction coefficient on a surface in contact with the semiconductor wafer is relatively small. Therefore, when the inertial force applied to the semiconductor wafer may exceed the resistance to lateral slippage, it is necessary to increase the electrostatic adsorption force. The electrostatic adsorption force is preferably small from the viewpoint of a withstand voltage of a component.

Further, since the adsorption force of the electrostatic chuck is proportional to an area, it is necessary to increase the area of the electrostatic chuck. Increasing the area of the electrostatic chuck makes it difficult to reduce a weight of the robot hand. Further, even after the electrostatic chuck is turned off, a residual adsorption force increases, and when the wafer is placed on a sample stage or the like, the wafer bounces and a positional displacement occurs.

An object of the present disclosure is, in a wafer transfer hand, to prevent a positional displacement of a wafer even when an electrostatic adsorption force is reduced and to prevent a wafer from bouncing due to a residual adsorption force.

### Solution to Problem

A wafer transfer hand according to an aspect of the present disclosure includes a hand main body, an electrostatic chuck, and an easily-deformable member, the electrostatic chuck and the easily-deformable member are disposed adjacent to each other on one plane of the hand main body, and the easily-deformable member has a height higher than that of the electrostatic chuck.

### Advantageous Effects of Invention

According to the present disclosure, in the wafer transfer hand, even when an electrostatic adsorption force is reduced, a positional displacement of the wafer can be prevented, and a wafer can be prevented from bouncing residual adsorption force.

### BRIEF DESCRIPTION OF DRAWINGS

FIG. 1 is a side view showing a wafer transfer hand according to Embodiment 1.

FIG. 2 is a side view showing a state where a warped wafer is placed on the wafer transfer hand in FIG. 1.

FIG. 3 is a perspective view showing the wafer transfer hand according to Embodiment 1.

FIG. 4 is a side view showing a wafer transfer hand according to Modification 1.

FIG. 5 is a side view showing an example of a preferable arrangement of an electrostatic chuck and a viscoelastic body.

FIG. 6 is a side view showing a wafer transfer hand according to Embodiment 2.

FIG. 7 is a side view showing a wafer transfer hand according to Modification 2.

FIG. 8 is a side view showing a state where a warped wafer is placed on the wafer transfer hand in FIG. 7.

FIG. 9 is a side view showing a wafer transfer hand according to Modification 3.

FIG. 10A is a side view showing a wafer transfer hand according to Modification 4.

FIG. 10B is a side view showing a state where an electrostatic chuck of the wafer transfer hand in FIG. 10A is turned on.

FIG. 11A is a side view showing the wafer transfer hand according to Embodiment 1.

FIG. 11B is a side view showing a state where an adsorption force is generated in the electrostatic chuck in FIG. 11A.

FIG. 12 is a perspective view showing an arrangement example of a laser displacement meter.

FIG. 13 is a flowchart showing an example of an operation of a wafer exchange device when the electrostatic chuck is disconnected.

FIG. 14 is a schematic cross-sectional view showing a semiconductor measurement device including the wafer transfer hand.

### DESCRIPTION OF EMBODIMENTS

First, a configuration and a principle for supporting a wafer by a wafer transfer hand according to the present disclosure will be described.

The wafer transfer hand includes a hand main body, an electrostatic chuck, and an easily-deformable member. The easily-deformable member includes a viscoelastic body.

In general, a viscoelastic body is a member made of a substance having both elastic properties and viscous properties as mechanical properties, and is made of a polymer material such as rubber.

Here, a condition under which a frictional force acts between the wafer and the viscoelastic body and the wafer does not slip is considered.

When the wafer is accelerated and moved in a horizontal direction, an inertial force F_{I} is applied to the wafer.

When the inertial force F_{I} is less than a frictional force F_{F}, the wafer does not slip. That is, a relationship of the following Formula (1) is established.

$${F}_{I} < {F}_{F} \qquad ( 1 )$$

The inertial force F_{I} applied to the wafer is expressed by the following Formula (2), in which M represents a mass of the wafer and A represents a maximum acceleration of a hand portion of a wafer exchange robot (wafer exchange device).

$${F}_{I} = M \times A \qquad ( 2 )$$

On the other hand, the frictional force F_{F} generated on a back surface (lower surface) of the wafer is expressed by the following Formula (3), in which G expresses a gravitational acceleration and u expresses a friction coefficient.

$$F = μ \times M \times G \qquad ( 3 )$$

When the above Formula (2) and Formula (3) are substituted into the above Formula (1), the following Formula (4) is obtained.

$$M \times A < μ \times M \times G \qquad ( 4 )$$

When M is eliminated from both sides, the following Formula (5) is obtained.

$$A < μ \times G \qquad ( 5 )$$

That is, since the gravitational acceleration G is constant, the maximum acceleration A uniquely depends on the friction coefficient μ, and speeding up of the wafer exchange robot is limited. In addition, when a resist or foreign matter adheres to the back surface of the wafer, there is a concern that the wafer may slip due to a decrease in the friction coefficient, and it is necessary to greatly estimate a safety factor of the acceleration. Therefore, it is difficult to speed up the wafer exchange robot.

A wafer transfer hand according to the present disclosure solves the above problem.

Hereinafter, embodiments of a wafer transfer hand, a wafer exchange device, a charged particle beam device, and a vacuum device according to the present disclosure will be described with reference to the drawings.

### Embodiment 1

The wafer exchange device includes a wafer transfer hand.

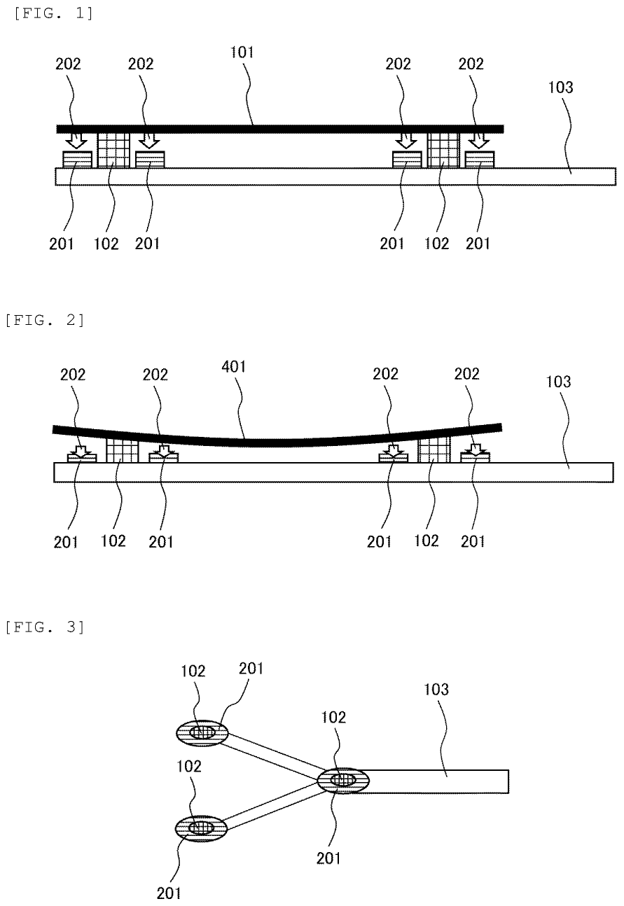

FIG. 1 is a side view showing a wafer transfer hand according to Embodiment 1.

The wafer transfer hand shown in FIG. 1 includes a hand main body 103, viscoelastic bodies 102, and electrostatic chucks 201. The viscoelastic bodies 102 and the electrostatic chucks 201 are provided on an upper surface of the hand main body 103. The upper surface of the hand main body 103 is planar.

The electrostatic chuck 201 is disposed around the viscoelastic body 102 so as to surround the viscoelastic body 102. The viscoelastic body 102 is higher than the electrostatic chuck 201. In this specification, such a structure in which the viscoelastic body 102 and the electrostatic chuck 201 are combined is referred to as a “composite adsorption hand structure”.

In other words, the electrostatic chuck 201 and the viscoelastic body 102 are disposed adjacent to each other on one plane of the hand main body 103.

A high voltage is applied to the electrostatic chuck 201 from an electrostatic chuck amplifier (not shown) to generate an electrostatic adsorption force between the electrostatic chuck 201 and a wafer 101.

The electrostatic chuck 201 may be an annular continuous body, or a plurality of columnar electrostatic chucks may be provided.

Since the viscoelastic body 102 is higher than the electrostatic chuck 201, an upper surface portion of the viscoelastic body 102 comes into contact with the wafer 101. On the other hand, the electrostatic chuck 201 generates an electrostatic adsorption force between the wafer 101 and the electrostatic chuck 201 without contacting the wafer 101.

That is, the wafer 101 is supported by the viscoelastic body 102, and a gap (space) is formed between the wafer 101 and the electrostatic chuck 201.

The electrostatic chuck 201 generates an adsorption force 202 for ensuring a real contact area between the viscoelastic body 102 and the back surface of the wafer 101. The adsorption force 202 is, for example, about 2 to 3 times the gravity applied to the wafer 101. The viscoelastic body 102 has a friction coefficient about one order of magnitude larger than that of the electrostatic chuck 201 having a surface provided with ceramics, polyimide, or the like as an insulating layer. Therefore, as compared with the case where only the electrostatic chuck 201 is used, it is possible to obtain the same degree of resistance to lateral slippage with the electrostatic adsorption force one order of magnitude smaller.

Since the required electrostatic adsorption force is small, an area of the electrostatic chuck 201 can be small, and a weight reduction of the wafer transfer hand can be implemented. In particular, it is advantageous to use a Coulomb force method capable of forming a f film laminated structure such as a polyimide film for the electrostatic chuck 201 for the weight reduction.

Further, since the electrostatic adsorption force is small, a residual adsorption force is also small, a wafer does not bounce, and a positional displacement does not occur.

Next, a handling of a warped wafer by the wafer transfer hand will be described.

FIG. 2 is a side view showing a state where a warped wafer is placed on the wafer transfer hand in FIG. 1.

The viscoelastic body 102 shown in FIG. 2 has a thickness (height) of about several hundred μm to several mm. With this configuration, when a warped wafer 401 is gripped, a surface shape of the viscoelastic body 102 can follow a sloped surface of the warped wafer 401. Accordingly, the real contact area can be made constant, a change in the friction coefficient and the resistance to lateral slippage can be prevented, and the warped wafer 401 can be stably held. That is, it is possible to contribute to speeding up the wafer exchange in a process of handling a warped wafer.

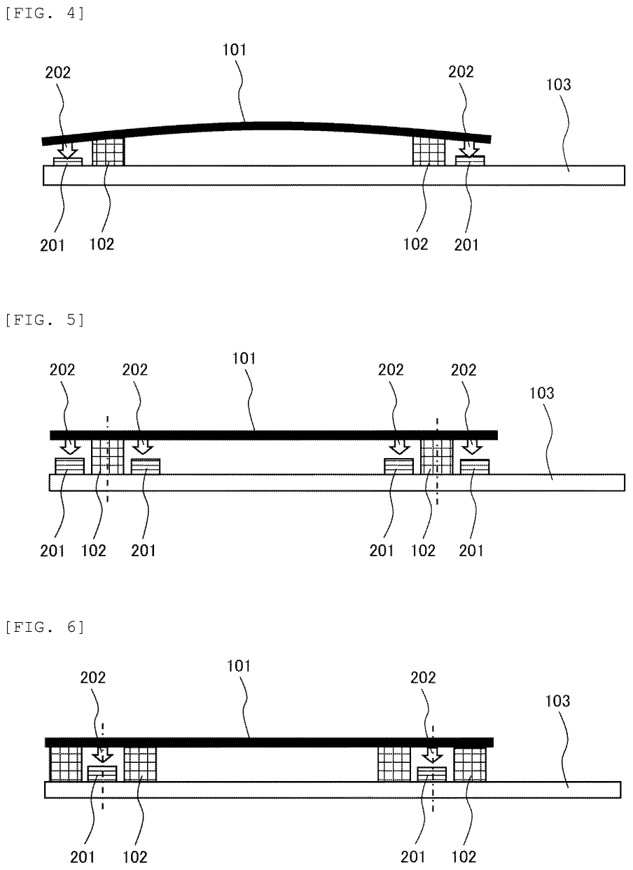

FIG. 3 is a perspective view showing the wafer transfer hand according to Embodiment 1.

In FIG. 3, the composite adsorption hand structure is supported at three points provided at three positions on the hand main body 103. The electrostatic chuck 201 is an annular continuous body, and is provided to surround the viscoelastic body 102.

In a case of two-point support, the wafer cannot be stably supported, and in a case of four-point support, rattling occurs when one point is higher or lower than the others.

On the other hand, in the case of the three-point support, since the plane is uniquely determined, it is possible to stably support the wafer without rattling.

FIG. 4 is a side view showing a wafer transfer hand according to Modification 1.

In FIG. 4, the electrostatic chuck 201 is disposed outside the viscoelastic body 102.

When an attractive force of the electrostatic chuck 201 is large, the wafer 101 may be deformed into an upward convex shape as shown in FIG. 4. Therefore, it is desirable to prevent deformation (bending) of the wafer 101 by limiting the attractive force of the electrostatic chuck 201 to a predetermined value or less.

FIG. 5 is a side view showing an example of a preferable arrangement of an electrostatic chuck and a viscoelastic body.

The viscoelastic body 102 is surrounded by the electrostatic chuck 201. In FIG. 4, two sets of the electrostatic chuck 201 and the viscoelastic body 102 are shown, but actually, three sets of the electrostatic chuck 201 and the viscoelastic body 102 are disposed as shown in FIG. 3. That is, it is desirable that the number of sets of the electrostatic chuck 201 and the viscoelastic body 102 disposed adjacent to each other is three. In this case, since the wafer 101 is not bent as a whole even when the adsorption force of the electrostatic chuck is applied, the wafer 101 does not vibrate even when the chuck is released, and the positional displacement does not occur.

### Embodiment 2

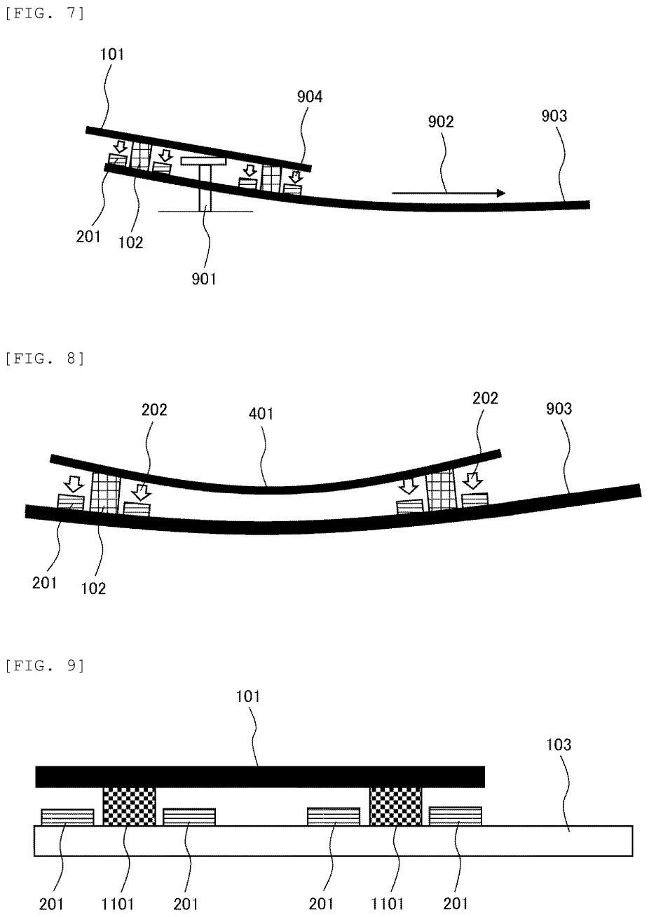

FIG. 6 is a side view showing a wafer transfer hand according to Embodiment 2.

In FIG. 6, the viscoelastic body 102 is disposed around the electrostatic chuck 201 so as to surround the electrostatic chuck 201. The viscoelastic body 102 is higher than the electrostatic chuck 201. This structure is also the “composite adsorption hand structure”.

Also in the case of this arrangement, similarly to the case of Embodiment 1 (FIG. 1), since the deformation in which the wafer 101 is bent as a whole does not occur, the wafer vibration or the positional displacement when the chuck is released does not occur.

In Embodiment 2, since the area where the viscoelastic body 102 comes into contact with the wafer 101 is larger than that in Embodiment 1, the frictional force can be ensured, and the positional displacement can be reliably prevented.

On the other hand, since it is easy to increase the area of the electrostatic chuck 201 in Embodiment 1 in FIG. 1, as compared with Embodiment 2, it is possible to secure the necessary electrostatic adsorption force at a low voltage.

Therefore, the configuration of Embodiment 1 or 2 is selected according to specifications of the wafer exchange device.

In both Embodiments 1 and 2 as well, the electrostatic chuck 201 or the viscoelastic body 102 disposed on an outer peripheral side of the composite adsorption hand structure may have a columnar shape or a prismatic shape.

FIG. 7 is a side view showing a wafer transfer hand according to Modification 2.

In FIG. 7, carbon fiber reinforced plastic (hereinafter referred to as “CFRP”) is used for a hand main body 903. Other configurations are the same as those in FIG. 1. Reference numeral 902 denotes a fiber direction of CFRP.

CFRP is known as a lightweight and high-attenuating material. By forming the hand main body 903 with CFRP, the hand main body 903 can be made lightweight. Further, the vibration of the wafer transfer hand can be quickly attenuated.

As a case where the vibration of the hand main body 903 becomes a problem, it is conceivable that when the wafer 101 is placed on a wafer support table 901 from the wafer transfer hand, the hand main body 903 is deformed by a minute residual adsorption force 904 of the electrostatic chuck 201, and the hand main body 903 vibrates at a moment when the wafer 101 is separated.

In the wafer transfer hand shown in FIG. 7, since the CFRP is used for the hand main body 903, such vibration at the time of delivery can be quickly attenuated. As shown in FIG. 7, a maximum attenuating effect can be obtained by setting the fiber direction 902 of the CFRP to a longitudinal direction of the hand main body 903.

Next, following of the warped wafer when the CFRP is used for the hand main body will be described.

FIG. 8 is a side view showing a state where a warped wafer is placed on the wafer transfer hand in FIG. 7.

In FIG. 8, since the hand main body 903 is formed of the CFRP, it is possible to induce the deformation of the hand main body 903 and further increase a following effect of the warped wafer 401. That is, robustness of the resistance to lateral slippage against wafer warpage can be further improved.

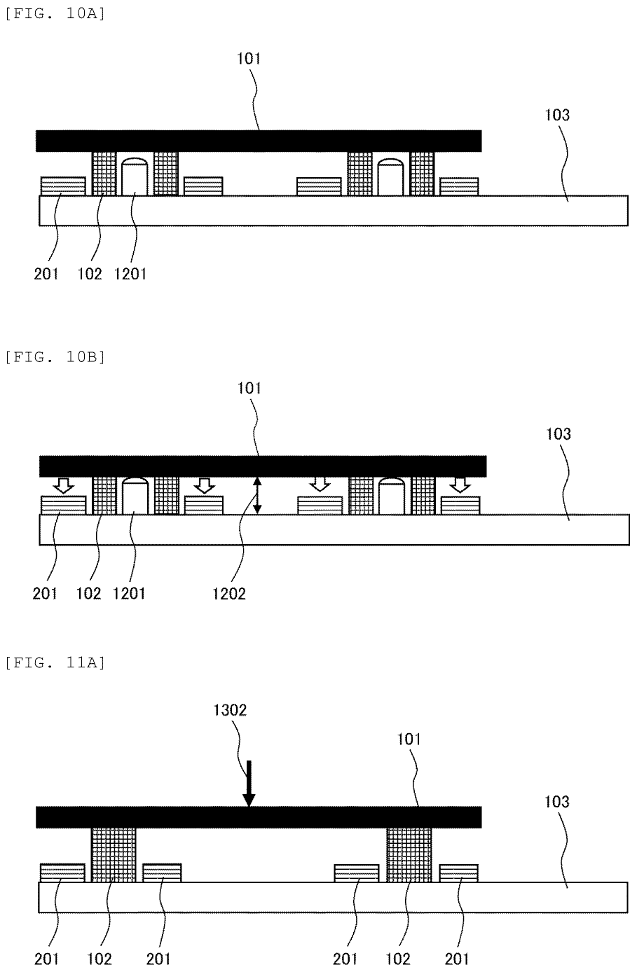

FIG. 9 is a side view showing a wafer transfer hand according to Modification 3.

The wafer transfer hand shown in FIG. 9 uses an atomic force pad 1101 instead of the viscoelastic body 102 shown in FIG. 1. Other configurations are the same as those in FIG. 1.

The atomic force pad 1101 can obtain the resistance to lateral slippage by adsorbing an object using an atomic force instead of a frictional force. Therefore, even when the state change of the back surface of the wafer such as adhesion of foreign matter, scattering of a chemical solution such as a resist, surface roughness, or variation occurs, it is possible to suppress a decrease in the resistance to lateral slippage as small as possible. That is, it is possible to improve the robustness against a state change of the back surface of the wafer.

Next, a description will be given of a configuration in which the viscoelastic body is an annular body (hollow cylindrical shape), and a protrusion is provided in a space in a center portion of the viscoelastic body to manage a gap between the viscoelastic body and an electrostatic chuck, so that an adsorption force is constant.

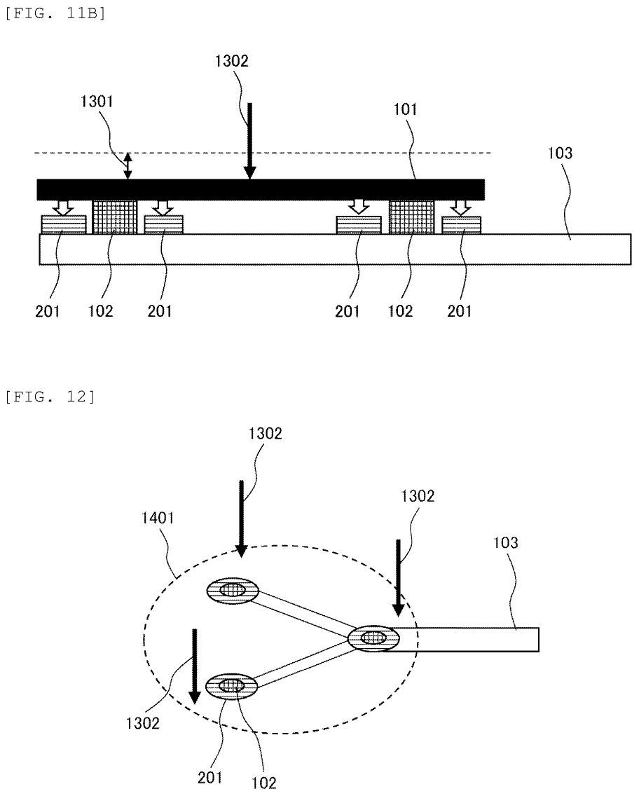

FIG. 10A is a side view showing a wafer transfer hand according to Modification 4.

In FIG. 10A, the viscoelastic body 102 is an annular body, and a protrusion 1201 is provided in a space of the center portion thereof. A height of the protrusion 1201 is lower than that of the viscoelastic body 102. The protrusion 1201 is formed of a material (hardly-deformable member) harder than the viscoelastic body 102.

FIG. 10B is a side view showing a state where the electrostatic chuck of the wafer transfer hand in FIG. 10A is turned on.

When the electrostatic chuck 201 is turned on to generate an adsorption force from the state of FIG. 10A, the wafer 101 comes into contact with the protrusion 1201 as shown in FIG. 10B. Accordingly, a gap 1202 between the wafer 101 and the electrostatic chuck 201 can be made constant.

The adsorption force of the electrostatic chuck 201 decreases in inverse proportion to a square of a distance to the wafer 101 as an adsorption target. By providing the protrusion 1201, the gap 1202 can be made constant, and the adsorption force of the electrostatic chuck 201 can be made constant. Further, since the adsorption force of the electrostatic chuck 201 becomes constant, it is possible to reduce the variation in the resistance to lateral slippage. This is also effective in reducing machine differences during mass production of the device.

The protrusion 1201 may be formed of a conductive resin such as conductive PEEK from the viewpoint of preventing the wafer 101 from being charged. Here, the PEEK is an abbreviation for polyether ether ketone.

In addition, since the protrusion 1201 is formed of the hardly-deformable member to make a position of the adsorbed wafer 101 constant, a position of the protrusion 1201 is not limited to the above example.

FIG. 11A is a side view showing the wafer transfer hand according to Embodiment 1.

FIG. 11B is a side view showing a state where an adsorption force is generated in the electrostatic chuck in FIG. 11A.

A configuration for detecting the adsorption force of the electrostatic chuck will be described with reference to these drawings.

In consideration of an operation of a composite adsorption hand of the present disclosure, when it is possible to check whether the electrostatic chuck is reliably operated or whether a desired adsorption force is obtained, it is effective to prevent the wafer from falling.

As shown in FIG. 11A, a laser displacement meter (not shown) is provided above the hand main body 103, and the wafer 101 is irradiated with an optical axis 1302 of the laser displacement meter.

Then, as shown in FIG. 11B, the adsorption force of the electrostatic chuck 201 is generated, and a sinking amount 1301 when the wafer 101 sinks is measured.

The sinking amount 1301 of the wafer 101 is calculated in advance from an elastic modulus and dimensions of the viscoelastic body 102, and is stored in a memory (not shown) of the device as a specified amount in a normal state. The specified amount in the normal state is used to determine the operation of the electrostatic chuck 201.

The laser displacement meter is provided, for example, on an upper surface of a sample chamber or an upper surface of a load lock chamber.

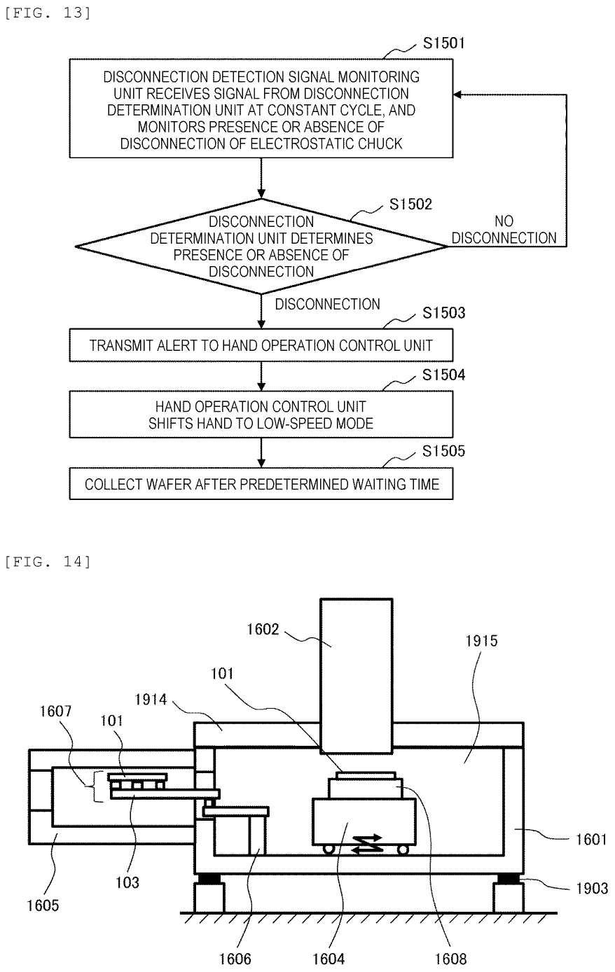

FIG. 12 is a perspective view showing an arrangement example of a laser displacement meter.

The laser displacement meter (not shown) can also be disposed to measure three points on a wafer outer peripheral portion 1401 indicated by broken lines. By calculating an inclination of the wafer by performing measurement at three points, it is possible to detect whether all of the three electrostatic chucks 201 are normally operated. By measuring displacement of the wafer outer peripheral portion 1401, the displacement due to the inclination of the wafer at the time of failure of the electrostatic chuck 201 is easily detected, so that failure detection can be performed even by using an inexpensive displacement sensor with relatively low accuracy.

FIG. 13 is a flowchart showing an example of an operation of a wafer exchange device when the electrostatic chuck is disconnected.

A configuration of a control unit of the wafer exchange device as a premise is as follows.

The control unit of the wafer exchange device includes an application voltage adjustment unit that adjusts a voltage generated by an electrostatic chuck amplifier that applies a high voltage to the electrostatic chuck, a disconnection determination unit that determines the presence or absence of disconnection of the electrostatic chuck, a disconnection detection signal monitoring unit that receives a signal of the determination result and monitors the presence or absence of disconnection, and a hand operation control unit. The hand operation control unit controls operations of the hand such as a moving distance, a moving speed, and a moving direction. In addition, the electrostatic chuck amplifier is provided with the disconnection detection signal monitoring unit that receives the signal of the determination result regarding the presence or absence of disconnection of the electrostatic chuck and monitors the presence or absence of disconnection.

As shown in FIG. 13, the disconnection detection signal monitoring unit receives a signal from the disconnection determination unit at a constant cycle, and monitors the presence or absence of disconnection of the electrostatic chuck (step S1501).

The disconnection determination unit determines the presence or absence of disconnection (step S1502), and when there is no disconnection, the process returns to step S1501 to continue monitoring.

On the other hand, when there is a disconnection, the signal is transmitted from the disconnection determination unit to the disconnection detection signal monitoring unit, and an alert is transmitted to the hand operation control unit (step S1503). When receiving the alert transmission, the hand operation control unit shifts the hand to a low-speed mode (step S1504). The low-speed mode is a mode in which the hand is operated within a range of an acceleration at which the wafer does not fall due to the frictional force of the viscoelastic body.

Thereafter, the wafer is collected after a certain waiting time (step S1505). The waiting time is preferably about 20 seconds.

At this time, since there is a processing delay time of a substrate, when the adsorption force is lost immediately after the electrostatic chuck is disconnected, the wafer may fall. In general, the processing delay time of the substrate is about several tens of milliseconds. However, when the electrostatic chuck is disconnected, since a chuck OFF process of forcibly applying a reverse voltage is not performed, a large residual adsorption force remains. Since the residual adsorption force gradually weakens over several seconds, a time during which most of the residual adsorption force remains, that is, a residual adsorption force maintenance time is about several seconds. Therefore, during the residual adsorption force maintaining time, that is, after the transition to the low-speed mode is completed, the residual adsorption force is maintained to some extent for several seconds, and the wafer does not fall from the hand. Further, by sufficiently setting the waiting time to about 20 seconds as described above, the residual adsorption force becomes almost zero, so that the wafer does not bounce when the wafer is collected by a lift or the like.

Finally, a semiconductor measurement device which is an embodiment of a charged particle beam device and a vacuum device according to the present disclosure will be described. The semiconductor measurement device according to the present embodiment is, for example, a length measurement SEM as an application device of a scanning electron microscope (SEM).

FIG. 14 is a schematic cross-sectional view showing a semiconductor measurement device including the wafer transfer hand.

The semiconductor measurement device shown in FIG. 14 includes a stage device 1604 that positions a target, a vacuum chamber 1601 that accommodates the stage device 1604, a lid 1914 that seals the vacuum chamber 1601, an electron optical system lens barrel 1602, a damping mount 1903, a load lock chamber 1605, and a wafer exchange robot 1606.

The stage device 1604 is accommodated in the vacuum chamber 1601. A space sealed by the vacuum chamber 1601 and the lid 1914 is a decompression chamber 1915. The decompression chamber 1915 is in a decompressed state at a pressure lower than an atmospheric pressure by a vacuum pump (not shown). The vacuum chamber 1601 is supported by the damping mount 1903.

The semiconductor measurement device positions the wafer 101 as a target such as a semiconductor wafer using the stage device 1604, irradiates the target with an electron beam from the electron optical system lens barrel 1602, images a pattern on the target, and measures a line width of the pattern and evaluates shape accuracy. The stage device 1604 controls positioning of a target such as the semiconductor wafer held on a sample stage 1608.

The load lock chamber 1605 is in a vacuum state when the wafer 101 is exchanged between the load lock chamber 1605 and the vacuum chamber 1601, and is in an atmospheric state when the wafer 101 is exchanged between the load lock chamber 1605 and the outside of the device. The wafer exchange robot 1606 is used to exchange the wafer 101 between the load lock chamber 1605 and the vacuum chamber 1601. The wafer exchange robot 1606 has a composite adsorption hand structure 1607.

Since the semiconductor measurement device according to the present embodiment includes the wafer exchange device having the composite adsorption hand structure, it is possible to perform an exchanging operation on a target such as a wafer at high speed with high positional accuracy. Therefore, it is possible to improve a throughput and inspection accuracy of the semiconductor measurement device as the charged particle beam device. Further, the composite adsorption hand can prevent the wafer displacement even when a foreign matter adheres to the back surface of the wafer by the atomic force pad or an adsorption force detection function, and can maintain high robustness with respect to positional accuracy during the wafer transfer.

Hereinafter, desired embodiments of the present disclosure will be collectively described.

In the wafer transfer hand, one of the electrostatic chuck and the easily-deformable member is disposed to surround the other one.

The number of sets of the electrostatic chuck and the easily-deformable member disposed adjacent to each other is desirably three.

The hand main body is made of carbon fiber reinforced plastic.

The electrostatic chuck has a configuration in which a surface thereof covered with a film.

The easily-deformable member has a surface structure using an atomic force.

The wafer transfer hand further includes a protrusion formed of a hardly-deformable member, and the easily-deformable member is higher than the protrusion.

The wafer exchange device includes a wafer transfer hand.

The charged particle beam device includes the wafer exchange device.

The charged particle beam device further includes a displacement sensor configured to measure a change in height of the wafer placed on the wafer transfer hand.

The vacuum device includes a wafer exchange device.

The vacuum device further includes a displacement sensor configured to measure a change in height of the wafer placed on the wafer transfer hand.

The charged particle beam device and the vacuum device of the present disclosure are not limited to the semiconductor measurement device.

Although the embodiments of the present disclosure have been described in detail with reference to the drawings, specific configurations are not limited to the embodiments describe above, and if design changes and the like may be made without departing from the gist of the present disclosure, the changes are included in the present disclosure.

### REFERENCE SIGNS LIST

101: wafer
102: viscoelastic body
103, 903: hand main body
201: electrostatic chuck
202: adsorption force
401: warped wafer
901: wafer support table
902: fiber direction of CFRP
904: residual adsorption force
1101: atomic force pad
1201: protrusion
1202: gap
1301: sinking amount
1302: optical axis
1401: wafer outer peripheral portion
1601: vacuum chamber
1602: electron optical system lens barrel
1604: stage device
1605: load lock chamber
1606: wafer exchange robot
1607: composite adsorption hand structure
1608: sample stage
1903: damping mount

1.-12. (canceled)

13. A wafer transfer hand comprising:
a hand main body;
an electrostatic chuck; and
an easily-deformable member, wherein
the electrostatic chuck and the easily-deformable member are disposed adjacent to each other on one plane of the hand main body,
the easily-deformable member has a height higher than that of the electrostatic chuck,
the wafer transfer hand further comprises
a protrusion formed of a hardly-deformable member, and
the easily-deformable member has a height higher than that of the protrusion.

14. The wafer transfer hand according to claim 13, wherein
one of the electrostatic chuck and the easily-deformable member is disposed so as to surround another one.

15. The wafer transfer hand according to claim 13, wherein
the number of sets of the electrostatic chuck and the easily-deformable member disposed adjacent to each other is three.

16. The wafer transfer hand according to claim 13, wherein
the hand main body is made of carbon fiber reinforced plastic.

17. The wafer transfer hand according to claim 13, wherein
the electrostatic chuck has a configuration in which a surface thereof covered with a film.

18. The wafer transfer hand according to claim 13, wherein
the easily-deformable member has a surface structure using an atomic force.

19. A wafer exchange device comprising:
the wafer transfer hand according to claim 13.

20. A charged particle beam device comprising:
the wafer exchange device according to claim 19.

21. The charged particle beam device according to claim 20, further comprising:
a displacement sensor configured to measure a change in height of the wafer placed on the wafer transfer hand.

22. A vacuum device comprising:
the wafer exchange device according to claim 19.

23. The vacuum device according to claim 22, further comprising:
a displacement sensor configured to measure a change in height of the wafer placed on the wafer transfer hand.
